(19) United States
(12) Patent Application Publication
(10) Pub. No.: US 2025/0181448 A1
(43) Pub. Date: Jun. 5, 2025

(54) MEMORY SCRUBBING BASED ON DETECTED CORRECTABLE ERROR

(71) Applicant: Micron Technology, Inc., Boise, ID (US)

(72) Inventors: Marco Sforzin, Cernusco Sul Naviglio MI (IT); Graziano Mirichigni, Vimercate (IT); Antonino Capri', Bergamo (IT); Danilo Caraccio, Milano (IT)

(21) Appl. No.: 18/953,694

(22) Filed: Nov. 20, 2024

Related U.S. Application Data
(60) Provisional application No. 63/605,817, filed on Dec. 4, 2023.

(51) Int. Cl. G06F 11/10

(52) U.S. Cl. CPC G06F 11/106; G06F 11/1016; G06F 11/1068

(57) ABSTRACT

A memory controller (e.g., for a memory device in a system such as a CXL system) can be configured to read first data from a first portion of an array of a memory device, determine a number of correctable errors present in the first data, and (1) in response to the number of correctable errors being less than a specified threshold number of correctable errors, perform a scrub operation using the first data, or (2) in response to the number of correctable errors being greater than a specified threshold number of correctable errors, disallow the scrub operation.

### PRIORITY APPLICATION

This application claims the benefit of priority to U.S. Provisional Application Ser. No. 63/605,817, filed Dec. 4, 2023, which is incorporated herein by reference in its entirety.

### BACKGROUND

Memory devices for computers or other electronic devices may be categorized as volatile and non-volatile memory. Volatile memory requires power to maintain its data, and includes random-access memory (RAM), dynamic random-access memory (DRAM), or synchronous dynamic random-access memory (SDRAM), among others. Non-volatile memory can retain stored data when not powered, and includes flash memory, read-only memory (ROM), electrically erasable programmable ROM (EEPROM), static RAM (SRAM), erasable programmable ROM (EPROM), resistance variable memory, phase-change memory, storage class memory, resistive random-access memory (RRAM), and magnetoresistive random-access memory (MRAM), among others. Persistent memory is an architectural property of the system where the data stored in the media is available after system reset or power-cycling. In some examples, non-volatile memory media may be used to build a system with a persistent memory model.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system.

Various protocols or standards can be applied to facilitate communication between a host and one or more other devices such as memory buffers, accelerators, or other input/output devices. In an example, an unordered protocol such as Compute Express Link (CXL) can be used to provide high-bandwidth and low-latency connectivity.

### BRIEF DESCRIPTION OF THE SEVERAL VIEWS OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally a block diagram of an example computing system including a host and a memory system.

FIG. 2 illustrates generally an example of a compute express link (CXL) system.

FIG. 3 illustrates generally an example of a CXL system implementing a virtual hierarchy for managing transactions.

FIG. 4A and FIG. 4B illustrate generally an example of a CXL memory device.

FIG. 5 illustrates a portion of a controller of a memory device.

FIG. 6 illustrates generally an example of different instances of a memory array.

FIG. 7 illustrates a portion of a controller of a memory device with a correctable error address list.

FIG. 8 illustrates an example of a method for identifying soft and hard errors in a memory device.

FIG. 9 illustrates a block diagram of an example machine with which, in which, or by which any one or more of the techniques discussed herein can be implemented.

### DETAILED DESCRIPTION

Compute Express Link (CXL) is an open standard interconnect configured for high-bandwidth, low-latency connectivity between host devices and other devices such as accelerators, memory devices, memory buffers, and other I/O devices. CXL was designed to facilitate high-performance computational workloads by supporting heterogeneous processing and memory systems. CXL enables coherency and memory semantics on top of PCI Express (PCIe)-based I/O semantics for optimized performance.

In some examples, CXL is used in applications such as artificial intelligence, machine learning, analytics, cloud infrastructure, edge computing devices, communication systems, and elsewhere. Data processing in such applications can use various scalar, vector, matrix and spatial architectures that can be deployed in CPU, GPU, FPGA, smart NICs, or other accelerators that can be coupled using a CXL link.

CXL supports dynamic multiplexing using a set of protocols that includes input/output (CXL.io, based on PCIe), caching (CXL.cache), and memory (CXL.memory or CXL.mem) semantics. In an example, CXL can be used to maintain a unified, coherent memory space between the CPU (e.g., a host device or host processor) and any memory on the attached CXL device. This configuration allows the CPU and the CXL device to share resources and operate on the same memory region for higher performance, reduced data movement, and reduced software stack complexity. In an example, the CPU is primarily responsible for maintaining or managing coherency in a CXL environment. Accordingly, CXL can be leveraged to help reduce device cost and complexity, as well as overhead traditionally associated with coherency across an I/O link.

CXL runs on PCIe PHY and provides full interoperability with PCIe. In an example, a CXL device starts link training in a PCIe Gen 1 Data Rate and negotiates CXL as its operating protocol (e.g., using the alternate protocol negotiation mechanism defined in the PCIe 5.0 specification) if its link partner supports CXL. Devices and platforms can thus more readily adopt CXL by leveraging the PCIe infrastructure and without having to design and validate the PHY, channel, channel extension devices, or other upper layers of PCIe.

In an example, CXL supports single level switching to enable fan-out to multiple devices. This enables multiple devices in a platform to migrate to CXL, while maintaining backward compatibility and the low-latency characteristics of CXL. In an example, CXL can provide a standardized compute fabric that supports pooling of multiple logical devices (MLD) and single logical devices such as using a CXL switch connected to several host devices or nodes (e.g., Root Ports). This feature enables servers to pool resources such as accelerators and/or memory that can be assigned according to workload. For example, CXL can help facilitate resource allocation or dedication and release. In an example, CXL can help allocate and deallocate memory to various host devices according to need. This flexibility helps designers avoid over-provisioning while ensuring best performance.

Some of the compute-intensive applications and operations mentioned herein can require or use large data sets. Memory devices that store such data sets can be configured for low latency and high bandwidth and persistence. One problem of a load-store interconnect architecture includes guaranteeing persistence. CXL can help address the problem using an architected flow and standard memory management interface for software, such as can enable movement of persistent memory from a controller-based approach to direct memory management.

The present inventors have recognized that a problem to be solved includes increasing the reliability of CXL memory devices. The problem can include determining when to perform memory scrubbing. An example of memory scrubbing can include (1) reading data from a particular memory location, (2) correcting one or more errors in the read data (e.g., using an error-correcting code (ECC) algorithm), and then (3) writing corrected data to the same particular memory location or to a different memory location. In an example, the problem can include memory devices that do not include or use an internal error correcting code (ECC) memory to detect and correct data corruption, such as DDR4 memory devices. Non-ECC memory generally cannot detect errors, however, some non-ECC memory includes parity information that can be used to detect errors. The inventors have further recognized that scrub operations for non-ECC memory can be initiated by system Reliability, Availability, and Serviceability (RAS) components that can degrade performance (e.g., in terms of processing time or bandwidth utilization) and can increase power consumption.

The present inventors have recognized that a solution to these and other problems can include performing a scrub operation when a particular type of correctable error (CE) occurs or when a pattern of multiple correctable errors occurs in a data block. In an example, the solution can include or use an error-detecting algorithm (e.g., configured to use an error-detecting and/or error-correcting code such as a Reed-Solomon (RS) code) to quantify any bit errors that are detected. That is, the error-detecting algorithm can determine a number of bit errors in a block of data. If more than a specified threshold number of CE errors is detected, then there can be a higher probability that the error(s) are due to a hard failure at the device periphery level. In another example, if more than the specified threshold number of CE errors is detected, then the portion of a die corresponding to the erroneous data may be more likely to have uncorrectable errors in the near future. Accordingly, memory scrubbing can be avoided when more than the specified threshold number of CE errors is detected for a particular block, for example, because scrubbing is less likely to be effective.

If the number of bit errors in a particular block is less than the specified threshold number of bit errors, then the particular block can be considered to have a correctable error and a scrub operation can be initiated to write corrected data back to the memory device (e.g., to the same memory or die location from which the data with an error was previously read). In an example, the scrub operation can be performed immediately after the CE is detected to avoid error accumulation. In other examples, the scrub operation can be postponed or scheduled for later performance by the system controller.

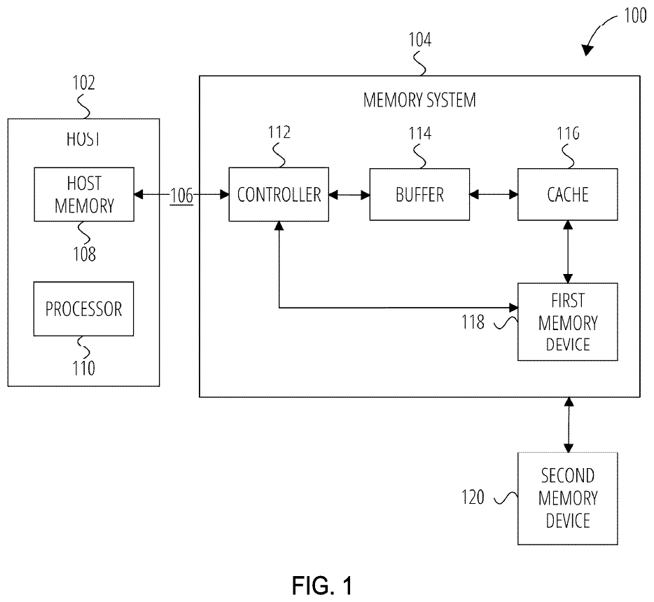

FIG. 1 illustrates generally a block diagram of an example of a computing system 100 including a host device 102 and a memory system 104. The host device 102 includes a central processing unit (CPU) or processor 110 and a host memory 108. In an example, the host device 102 can include a host system such as a personal computer, a desktop computer, a digital camera, a smart phone, a memory card reader, and/or Internet-of-things enabled device, among various other types of hosts, and can include a memory access device, e.g., the processor 110. The processor 110 can include one or more processor cores, a system of parallel processors, or other CPU arrangement.

The memory system 104 includes a controller 112, a buffer 114, a cache 116, and a first memory device 118. The first memory device 118 can include, for example, one or more memory modules (e.g., single in-line memory modules, dual in-line memory modules, etc.). The first memory device 118 can include volatile memory and/or non-volatile memory, and can include a multiple-chip device that comprises one or multiple different memory types or modules. In an example, the computing system 100 includes a second memory device 120 that interfaces with the memory system 104 and the host device 102.

The host device 102 can include a system backplane and can include a number of processing resources (e.g., one or more processors, microprocessors, or some other type of controlling circuitry). The computing system 100 can optionally include separate integrated circuits for the host device 102, the memory system 104, the controller 112, the buffer 114, the cache 116, the first memory device 118, the second memory device 120, any one or more of which may comprise respective chiplets that can be connected and used together. In an example, the computing system 100 includes a server system and/or a high-performance computing (HPC) system and/or a portion thereof. Although the example shown in FIG. 1 illustrates a system having a Von Neumann architecture, embodiments of the present disclosure can be implemented in non-Von Neumann architectures, which may not include one or more components (e.g., CPU, ALU, etc.) often associated with a Von Neumann architecture.

In an example, the first memory device 118 can provide a main memory for the computing system 100, or the first memory device 118 can comprise accessory memory or storage for use by the computing system 100. In an example, the first memory device 118 or the second memory device 120 includes one or more arrays of memory cells, e.g., volatile and/or non-volatile memory cells. The arrays can be flash arrays with a NAND architecture, for example. Embodiments are not limited to a particular type of memory device. For instance, the memory devices can include RAM, ROM, DRAM, SDRAM, PCRAM, RRAM, and flash memory, among others.

In embodiments in which the first memory device 118 includes persistent or non-volatile memory, the first memory device 118 can include a flash memory device such as a NAND or NOR flash memory device. The first memory device 118 can include other non-volatile memory devices such as non-volatile random-access memory devices (e.g., NVRAM, ReRAM, FeRAM, MRAM, PCM), memory devices such as a ferroelectric RAM device that includes ferroelectric capacitors that can exhibit hysteresis characteristics, a 3-D Crosspoint (3D XP) memory device, etc., or combinations thereof.

In an example, the controller 112 comprises a media controller such as a non-volatile memory express (NVMe) controller. The controller 112 can be configured to perform operations such as copy, write, read, error correct, etc. for the first memory device 118. In an example, the controller 112 can include purpose-built circuitry and/or instructions to perform various operations. That is, in some embodiments, the controller 112 can include circuitry and/or can be configured to perform instructions to control movement of data and/or addresses associated with data such as among the buffer 114, the cache 116, and/or the first memory device 118 or the second memory device 120.

In an example, at least one of the processor 110 and the controller 112 comprises a command manager (CM) for the memory system 104. The CM can receive, such as from the host device 102, a read command for a particular logic row address in the first memory device 118 or the second memory device 120. In some examples, the CM can determine that the logical row address is associated with a first row based at least in part on a pointer stored in a register of the controller 112. In an example, the CM can receive, from the host device 102, a write command for a logical row address, and the write command can be associated with second data. In some examples, the CM can be configured to issue, to non-volatile memory and between issuing the read command and the write command, an access command associated with the first memory device 118 or the second memory device 120. In some examples, the CM can issue, to the non-volatile memory and between issuing the read command and the write command, an access command associated with the first memory device 118 or the second memory device 120.

In an example, the buffer 114 comprises a data buffer circuit that includes a region of a physical memory used to temporarily store data, for example, while the data is moved from one place to another. The buffer 114 can include a first-in, first-out (FIFO) buffer in which the oldest (e.g., the first-in) data is processed first. In some embodiments, the buffer 114 includes a hardware shift register, a circular buffer, or a list.

In an example, the cache 116 comprises a region of a physical memory used to temporarily store particular data that is likely to be used again. The cache 116 can include a pool of data entries. In some examples, the cache 116 can be configured to operate according to a write-back policy in which data is written to the cache without being concurrently written to the first memory device 118. Accordingly, in some embodiments, data written to the cache 116 may not have a corresponding data entry in the first memory device 118.

In an example, the controller 112 can receive write requests (e.g., from the host device 102) involving the cache 116 and cause data associated with each of the write requests to be written to the cache 116. In some examples, the controller 112 can receive the write requests at a rate of thirty-two (32) gigatransfers (GT) per second, such as according to or using a CXL protocol. The controller 112 can similarly receive read requests and cause data stored in, e.g., the first memory device 118 or the second memory device 120, to be retrieved and written to, for example, the host device 102 via an interface 106.

In an example, the interface 106 can include any type of communication path, bus, or the like that allows information to be transferred between the host device 102 and the memory system 104. Non-limiting examples of interfaces can include a peripheral component interconnect (PCI) interface, a peripheral component interconnect express (PCIe) interface, a serial advanced technology attachment (SATA) interface, and/or a miniature serial advanced technology attachment (mSATA) interface, among others. In an example, the interface 106 includes a PCIe 5.0 interface that is compliant with the compute express link (CXL) protocol standard. Accordingly, in some embodiments, the interface 106 supports transfer speeds of at least 32 GT/s.

As similarly described elsewhere herein, CXL is a high-speed central processing unit (CPU)-to-device or CPU-to-memory interconnect designed to enhance compute performance. CXL technology maintains memory coherency between a CPU memory space (e.g., the host memory 108) and memory on attached devices or accelerators (e.g., the first memory device 118 or the second memory device 120), which allows resource sharing for higher performance, reduced software stack complexity, and lower overall system cost. CXL is designed to be an industry open standard interface for high-speed communications as accelerators are increasingly used to complement CPUs in support of emerging data-rich and compute-intensive applications such as artificial intelligence and machine learning.

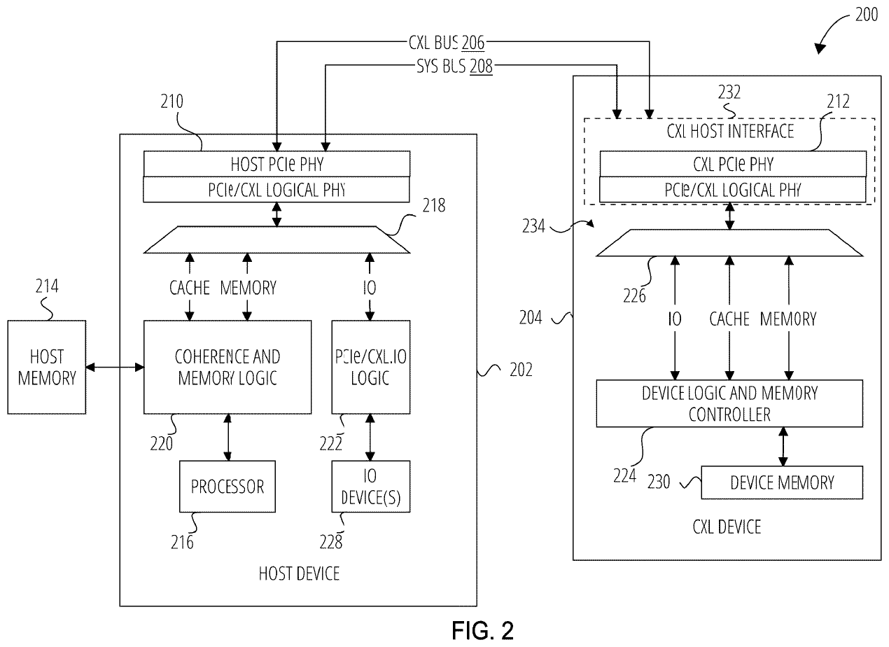

FIG. 2 illustrates generally an example of a CXL system 200 that uses a bus system, including a CXL link bus 206 and a system management bus 208, to connect a host device 202 and a CXL device 204. In an example, the host device 202 comprises or corresponds to the host device 102 and the CXL device 204 comprises or corresponds to the memory system 104 from the example of the computing system 100 in FIG. 1. A memory system command manager (CM) can comprise a portion of the host device 202 or the CXL device 204.

In an example, the system management bus 208 (e.g., corresponding to a portion of the interface 106 from the example of FIG. 1) is configured to support main-band or side-band communications between the host device 202 and the CXL device 204. The system management bus 208 can carry miscellaneous commands or events using PCIe and CXL protocols, such as link speed changes, reset commands issued by the host, and other reliability, availability, and serviceability features.

In an example, the CXL link bus 206 (e.g., corresponding to a portion of the interface 106 from the example of FIG. 1) can support communications using multiplexed protocols for caching (e.g., CXL.cache), memory accesses (e.g., CXL.mem or CXL.memory), and data input/output transactions (e.g., CXL.io). CXL.io can include a protocol based on PCIe that is used for functions such as device discovery, configuration, initialization, I/O virtualization, and direct memory access (DMA) using non-coherent load-store, producer-consumer semantics. CXL.cache can enable a device to cache data from the host memory (e.g., from the host memory 214) using a request and response protocol. CXL.memory can enable the host device 202 to use memory attached to the CXL device 204, for example, in or using a virtualized memory space. The CXL-based memory device can include or use a volatile or non-volatile memory such as can be characterized by different speeds or latencies. In an example, the CXL-based memory device can include a CXL-based memory controller configured to manage transactions with the volatile or non-volatile memory.

In an example, CXL.memory transactions can be memory load and store operations that run downstream from or outside of the host device 202. CXL memory devices can have different levels of complexity. For example, a simple CXL memory system can include a CXL device that includes, or is coupled to, a single media controller, such as a memory controller (MEMC). A moderate CXL memory system can include a CXL device that includes, or is coupled to, multiple media controllers. A complex CXL memory system can include a CXL device that includes, or is coupled to, a cache controller (and its attendant cache) and to one or more media or memory controllers.

In the example of FIG. 2, the host device 202 includes a host processor 216 (e.g., comprising one or more CPUs or cores) and IO device(s) 228. The host device 202 can comprise, or can be coupled to, host memory 214. The host device 202 can include various circuitry or logic configured to facilitate CXL-based communications and transactions with the CXL device 204. For example, the host device 202 can include coherence and memory logic 220 configured to implement transactions according to CXL.cache and CXL.memory semantics, and the host device 202 can include PCIe logic 222 configured to implement transactions according to CXL.io semantics. In an example, the host device 202 can be configured to manage coherency of data cached at the CXL device 204 using, e.g., its coherence and memory logic 220.

The host device 202 can further include a host multiplexer 218 configured to modulate communications over the CXL link bus 206 (e.g., using the PCIe PHY layer). The multiplexing of protocols ensures that latency-sensitive protocols (e.g., CXL.cache and CXL.memory) have the same or similar latency as a native processor-to-processor link. In an example, CXL defines an upper bound on response times for latency-sensitive protocols to help ensure that device performance is not adversely impacted by variation in latency between different devices implementing coherency and memory semantics.

In an example, symmetric cache coherency protocols can be difficult to implement between host processors because different architectures may use different solutions, which in turn can compromise backward compatibility. CXL can address this problem by consolidating the coherency function at the host device 202, such as using the coherence and memory logic 220.

CXL devices can include devices with various different architectures and capabilities. For example, a Type 1 CXL device can be a device configured to implement a fully coherent cache without host management. Transaction types used with Type 1 devices can include device-to-host (D2H) coherent transactions and host-to-device (H2D) snoop transactions, among others. A Type 2 CXL device, such as can include or use an attached high-bandwidth memory, can be configured to optionally implement coherent cache and can be host-managed. CXL.cache and CXL.mem transactions are generally supported by Type 2 devices. A Type 3 CXL device, such as a memory expander for the host, can be configured to include or use host-managed memory. A Type 3 device supports CXL.mem transactions.

The CXL device 204 can include various components or logical blocks including a CXL host interface 232 and a device management system 234. In an example, the CXL host interface 232 can be configured to receive and manage various requests and transactions. For example, the CXL host interface 232 can be configured to receive and communicate PCIe resets such as using PERST (PCI Express Reset), Hot Reset, FLR (function level reset), and CXL resets. In an example, the CXL host interface 232 can be configured to receive and communicate DOE Transaction layer packets. In an example, the CXL host interface 232 can be configured to handle side-band requests or other miscellaneous events from PCIe and CXL devices, such as using the CXL link bus 206 or the system management bus 208.

The CXL host interface 232 can include or use multiple CXL interface physical layers 212. The device management system 234 can include, among other things, the device logic and memory controller 224. In an example, the CXL device 204 can comprise a device memory 230, or can be coupled to another memory device. The CXL device 204 can include various circuitry or logic configured to facilitate CXL-based communications and transactions with the host device 202 using the CXL link bus 206. For example, the device logic and memory controller 224 can be configured to implement transactions received using the CXL host interface 232 according to CXL.cache, CXL.memory, and CXL.io semantics. The CXL device 204 can include a CXL device multiplexer 226 configured to control communications over the CXL link bus 206.

In an example, one or more of the coherence and memory logic 220, the device management system 234, and the device logic and memory controller 224 comprises a Unified Assist Engine (UAE) or compute fabric with various functional units such as a command manager (CM), Threading Engine (TE), Streaming Engine (SE), Data Manager or data mover (DM), or other unit. The compute fabric can be reconfigurable and can include separate synchronous and asynchronous flows.

The device management system 234 or the device logic and memory controller 224 or portions thereof can be configured to operate in an application space of the CXL system 200 and, in some examples, can initiate its own threads or sub-threads, which can operate in parallel and can optionally use resources or units on other CXL devices 204. Queue and transaction control through the system can be coordinated by the CM, TE, SE, or DM components of the UAE. In an example, each queue or thread can map to a different loop iteration to thereby support multi-dimensional loops. With the capability to initiate such nested loops, among other capabilities, the system can realize significant time savings and latency improvements for compute-intensive operations.

In an example, command fencing can be used to help maintain order throughout such operations, which can be performed locally or throughout a compute space of the device logic and memory controller 224. In some examples, the CM can be used to route commands to a particular command execution unit (e.g., comprising the device logic and memory controller 224 of a particular instance of the CXL device 204) using an unordered interconnect that provides respective transaction identifiers (TID) to command and response message pairs.

In an example, the CM can coordinate a synchronous flow, such as using an asynchronous fabric of the reconfigurable compute fabric to communicate with other synchronous flows and/or other components of the reconfigurable compute fabric using asynchronous messages. For example, the CM can receive an asynchronous message from a dispatch interface and/or from another flow controller instructing a new thread at or using a synchronous flow. The dispatch interface may interface between the reconfigurable compute fabric and other system components. In some examples, a synchronous flow may send an asynchronous message to the dispatch interface to indicate completion of a thread.

Asynchronous messages can be used by synchronous flows such as to access memory. For example, the reconfigurable compute fabric can include one or more memory interfaces. Memory interfaces are hardware components that can be used by a synchronous flow or components thereof to access an external memory that is not part of the synchronous flow but is accessible to the host device 202 or the CXL device 204. A thread executed using a synchronous flow can include sending a read and/or write request to a memory interface. Because reads and writes are asynchronous, the thread that initiates a read or write request to the memory interface may not receive the results of the request. Instead, the results of a read or write request can be provided to a different thread executed at a different synchronous flow. Delay and output registers in one or more of the CXL devices 204 can help coordinate and maximize efficiency of a first flow, for example, by precisely timing engagement of particular compute resources of one device with arrival of data relevant to the first flow. The registers can help enable the particular compute resources of the same resource to be repurposed for flows other than the first flow, for example while the first flow dwells or waits for other data or operations to complete. Such other data or operations can depend on one or more other resources of the fabric.

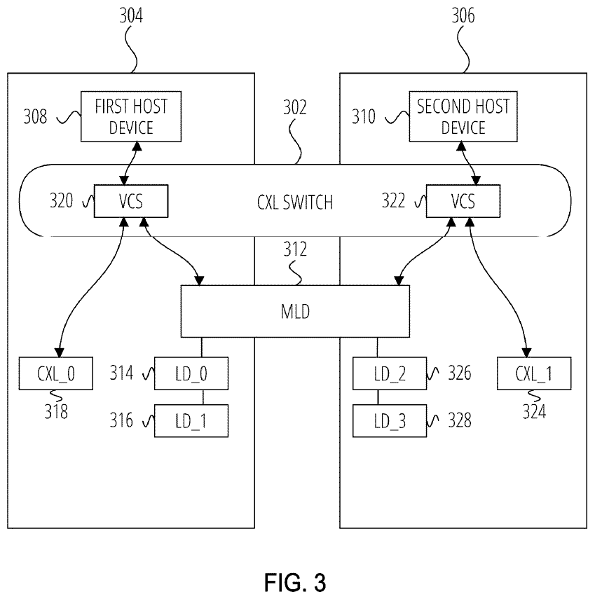

FIG. 3 illustrates generally an example of a portion of a CXL system that can include or use a virtual hierarchy for managing transactions, such as memory transactions with a CXL memory device. The example can include or use real-time telemetry to help facilitate allocation of new or ongoing queues. The example of FIG. 3 includes a first virtual hierarchy 304 and a second virtual hierarchy 306. The first virtual hierarchy 304, the second virtual hierarchy 306, or one or more modules or components thereof can be implemented using the host device 202, the CXL device 204, or multiple instances of the host device 202 or the CXL device 204.

In the example of FIG. 3, the first virtual hierarchy 304 includes a first host device 308 and the second virtual hierarchy 306 includes a second host device 310. A CXL switch 302 can be provided to expose multiple CXL resources to different hosts in the system. In other words, the CXL switch 302 can be configured to couple each of the first host device 308 and the second host device 310 to the same or different resources, such as using respective virtual CXL switches (VCS), such as a first VCS 320 and a second VCS 322, respectively. The CXL switch 302 can be statically configured to couple each host device to respective different resources or the CXL switch 302 can be dynamically configured to the different resources, such as depending on the needs of a particular one of the host devices to execute its respective queues or threads. Accordingly, the CXL switch 302 enables virtual hierarchies and resource sharing among different hosts.

In an example, a fabric manager (FM) can be provided to assign or coordinate connectivity of the CXL switch 302 and can be configured to initiate, dissolve, or reconfigure the virtual hierarchies of the CXL system. The FM can include a baseboard management controller (BMC), an external controller, a centralized controller, or other controller.

In the example of FIG. 3, the CXL switch 302, or the first VCS 320 or the second VCS 322, can coordinate communication between the host devices and various accelerators or other CXL devices. For example, the CXL switch 302 can be coupled to various CXL devices (e.g., a first CXL device 318 or a second CXL device 324), or to various logical devices, such as a single logical device (LD, e.g., a first LD 314, a second LD 316, a third LD 326, or a fourth LD 328) via a multiple logic device (MLD, e.g., an MLD 312). Each CXL device and logical device can represent a respective accelerator or CXL device with its own respective CXL.io configuration space, CXL.mem memory space, and CXL.cache cache space.

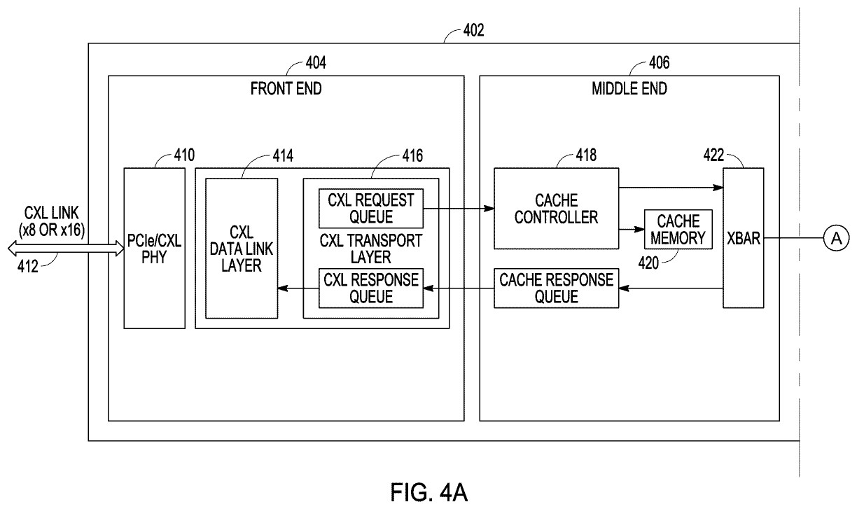

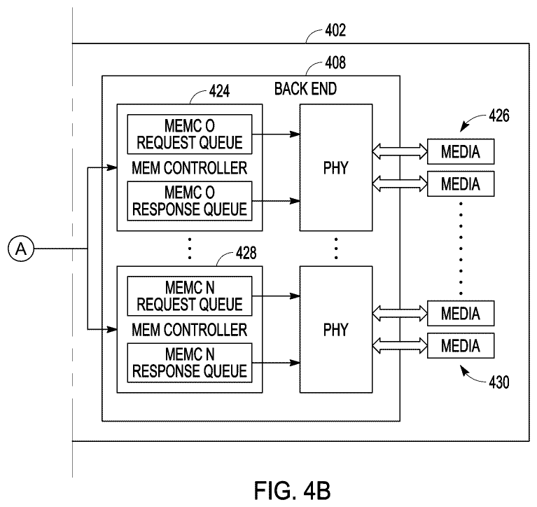

FIG. 4A and FIG. 4B illustrate generally an example of a CXL device 402 such as can include a memory device. In an example, the CXL device 402 includes a CXL controller that manages transactions with the host and the CXL device 402 includes a memory controller that manages transactions with a memory. The memory can include or use a volatile memory such as DRAM, SDRAM, PCRAM, RRAM, among other kinds of memory. The memory can additionally or alternatively include or use non-volatile memory, such as NAND or NOR flash memory. Although the host and other CXL devices are discussed in various examples herein as a “CXL” host device and a “CXL” accelerator or “CXL” device, other types of hosts and accelerators can similarly be used without including or using CXL protocols.

In an example, the CXL device 402 is a type of accelerator device configured to communicate with one or more hosts via a CXL interface, such as using transactions defined by CXL.io, CXL.mem, and CXL.cache protocols. The CXL device 402 can include a Type 3 CXL device, such as including a memory device with one or multiple memories, such as can include memories of the same type or of different types (e.g., memories exhibiting respective different latency characteristics).

For ease of illustration and discussion, the example of the CXL device 402 includes a notional front-end portion 404, a middle-end portion 406, and a back-end portion 408. The portions and components thereof of the CXL device 402 can be differently configured or combined according to different implementations of the CXL device 402.

In the example of FIG. 4A, the front-end portion 404 can include a CXL link 412 configured to use a physical layer, CXL PCIe PHY layer 410, to interface with a host device. The front-end portion 404 can further include a CXL data link layer 414 and a CXL transport layer 416 configured to manage transactions between the CXL device 402 and the host. In an example, the CXL transport layer 416 comprises registers and operators configured to manage CXL request queues (e.g., comprising one or more memory transaction requests) and CXL response queues (e.g., comprising one or more memory transaction responses) for the CXL device 402.

In an example, the CXL device 402 can include a memory device that includes a cache (e.g., comprising SRAM) and includes longer-term volatile or non-volatile memory accessible via a memory controller. In the example of FIG. 4A and FIG. 4B, the CXL device 402 includes a cache memory 420 in the middle-end portion 406 of the device. The middle-end portion 406 can include a cache controller 418 configured to monitor requests from the CXL transport layer 416 and identify requests that can be fulfilled using the cache memory 420.

Various complexities can arise in CXL systems. For example, CXL transactions can be based on a relatively large transaction size (e.g., 64 bytes), while some processes may use more granularity or smaller data sizes. Accordingly, in some examples, the cache controller 418 can be included or used in the CXL device 402 to store excess data fetched from backend media controllers or memories, such as from one or more memories in the back-end portion 408 of the CXL device 402.

In a particular example, such as including or using the CXL device 402 with DDR4 or DDR5 attached memory, sideband ECC can be supported or used to help protect data integrity. When the transaction size is 64 bytes, a relatively large amount of ECC data can be retrieved at once, while only a portion of the ECC data may be used for a particular transaction. The excess ECC data can be stored using the cache memory 420 for more efficient access, thereby helping reduce latency for future transactions.

In an example, the cache controller 418 is coupled to a cross-bar interface or XBAR interface 422. The XBAR interface 422 can be configured to allow multiple requesters to access multiple memory controllers in parallel, such as including multiple memory controllers in the back-end portion 408 of the CXL device 402. In an example, the XBAR interface 422 provides essentially point-to-point access between the requestor and memory controller and provides generally higher performance than would be available using a conventional bus architecture. The XBAR interface 422 can be configured to receive responses from the back-end portion 408 or receive cache hits from the cache memory 420 and deliver the responses to the front-end portion 404 using a cache response queue.

At FIG. 4B, the back-end portion 408 of the CXL device 402 includes multiple memory controllers, including a first memory controller 424 through a Nth memory controller 428. Each of the memory controllers can have or use respective memory request and response queues. Each of the memory controllers can be coupled to respective media or memories, such as can comprise volatile or non-volatile memory. In the illustrated example, the first memory controller 424 is coupled to a first memory 426 and the Nth memory controller 428 is coupled to a Nth memory 430.

In an example, each of the multiple memory controllers in the system can manage its own respective queues. In some examples, different memory controllers can be configured to use or interface with memories having respective different latency characteristics. Accordingly, performance optimization can include coordination of the respective queues of each memory controller. Informed coordination can be based on, for example, request and response path information for each memory controller.

In an example, the memory device of the CXL device 402 can include a memory array that does not include or use on-die ECC. In this case, random errors in the memory array can be corrected at or using the memory controller (e.g., the first memory controller 424, the Nth memory controller 428, etc.). For example, the controller can be configured to use a Reed-Solomon (RS) code to identify or correct errors in data retrieved from the memory array. In an example, the controller accesses data provided by multiple dies (e.g., 18 dies) that are accessed in parallel (e.g., using a 72-bit channel). For example, each die can use multiple data in or data out pins (DQ pins), such as four pins per die. In an example that can include a CXL memory device, the minimum transaction size can be 64 bytes. Accordingly, in an 18 die device where 2 dies comprise parity information (e.g., Reed-Solomon code data), each die provides 4 bytes of data to thereby provide a 64 byte transaction or block of data.

In an example, a scrub operation can be performed. The scrub operation can include one or more of reading data, correcting data, and writing data. In an example, a scrub operation includes reading data from a particular location or address in a memory array and identifying a correctable error (CE). The CE can be identified using an error detecting algorithm, for example, using a Reed-Solomon code, BCH code, or other code.

In an example, the CE can be identified by a decoding engine that is configured to apply an error-correcting code. In an example, the decoding engine can be configured to provide corrected data. The scrub operation can include, for example, writing the corrected data back to the same particular location or address in the memory array from which the data (with error(s)) was originally or previously read.

Some cells inside the memory array may continue to contain incorrect data even after a scrub operation. The present inventors have recognized that future device failures can be indicated when errors persist or accumulate, including after scrub operations are performed.

The present inventors have further recognized that a scrub operation can be based on, or can be conditionally performed in response to, an error pattern that is identified by the decoding engine and controller. In other words, some scrub operations can be avoided (and other ECC techniques applied) when such operations are less likely to be effective at remedying particular errors or error patterns.

In some examples, a scrub operation can include re-writing data immediately following the read operation to exploit the already-open row, and thus avoid a specific activate command. This approach can help optimize the system and avoid error accumulation in memory (e.g., DRAM) components.

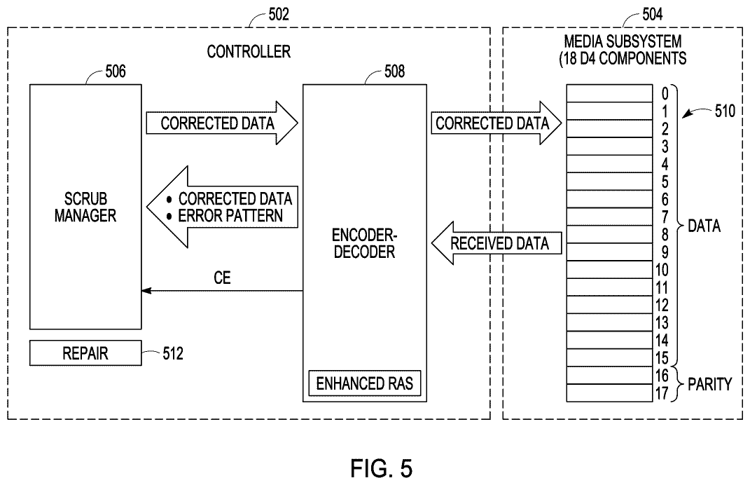

FIG. 5 illustrates generally an example of a portion of the CXL device 402 including a memory controller 502 and a media subsystem 504. The media subsystem 504 can comprise a memory array 510, such as comprising multiple dies (e.g., 18 dies). The memory controller 502 can include, among other things, a scrub manager 506, an error encoder-decoder 508, a repair 512 module configured to perform other data repairs (e.g., for errors outside the scope of the error encoder-decoder 508). In an example, the error encoder-decoder 508 comprises an enhanced RAS module configured to perform other reliability, availability and serviceability mechanisms for the memory device.

In the example of FIG. 5, 16 dies comprise data and 2 dies comprise parity information for use with the data. In an example, a data burst from the media subsystem 504 comprises 72 symbols, with 8 symbols representing the parity information, such as can comprise a Reed-Solomon (RS) code. RS code can correct up to 4 symbols of error in this example, and 4 symbols are provided per die. Thus, even if a particular die is unavailable or faulty, the RS code can be used to correct the data provided by the chip, provided there are no additional errors.

The media subsystem 504 can provide a burst of data to the memory controller 502 and the data can be received by an error encoder-decoder 508. The error encoder-decoder 508 can be configured to process the received data to determine, among other things, whether one or more correctable errors are present in the received data. Output from the error encoder-decoder 508 can include, for example, one or more of an indication of whether an error was detected, corrected data (e.g., if one or more correctable errors are found), and information about the error pattern. In an example, the output from the error encoder-decoder 508 includes information about the outcome of applying the RS code check, and can further include information about uncorrectable errors, if encountered.

The scrub manager 506 can be configured to use information about the error pattern to determine whether to allow re-writing the data to the same memory location from which the data was originally or previously read. That is, the scrub manager 506 can receive information about the CE error pattern and can receive the corrected data from the error encoder-decoder 508 and, in response, the scrub manager 506 can be configured to determine whether and where to write the data back to the media subsystem 504 or take a different action.

In an example, the scrub manager 506 can be configured to use information from the error encoder-decoder 508 to distinguish between random errors or “soft” errors corresponding to a discrete number of bits or cells, such as 1 or 2 cells, and periphery failures corresponding to a relatively large number of bits or cells, such as 3 or more cells. In an example, periphery failures that correspond to a large number of cells can be considered “hard” errors and may be uncorrectable or indicative of a device failure. The scrub manager 506 can be configured to allow a scrub operation to proceed for detected soft or random errors. The scrub manager 506 can be configured to disallow scrub operations for periphery failures or hard errors. In an example, the scrub manager 506 can be configured to disallow scrub operations for random or soft errors that meet or exceed a threshold count or weight of errors in a particular region or die of the memory array.

The present inventors have recognized that information about a correctable error pattern can be used to distinguish between random errors and periphery failures. In an example, the correctable error pattern includes a count of a number of symbols corrected by the error encoder-decoder 508. If the count of corrected symbols is greater than a specified threshold count or weight, then it is unlikely that the error is a random error, and corrective action other than a scrub operation can be initiated. Functions other than a count can similarly be used to determine the weight of the observed errors in the output of the error encoder-decoder 508. In an example, a Hamming weight can be determined and used to determine whether to perform a scrub operation. A number of ones can be counted in the data stream of each die. This count can be considered the Hamming weight of the pattern in the data stream of each respective die. The weight can be computed by adding the weight of the symbols impacted by the error. The weight can be compared to a specified threshold and used to determine whether to proceed with a scrub operation (e.g., when the weight does not exceed the threshold) or to disallow a scrub operation (e.g., when the weight exceeds the threshold).

Stated differently, if less than a threshold number of errors (e.g., correctable errors) is identified by the error encoder-decoder 508 for a particular die, then a scrub operation can be initiated and performed. Since the error count does not exceed the threshold, the system can allow and provision the appropriate resources (e.g., power, bandwidth) to write data back to the array or media subsystem 504. If more than the threshold number of correctable errors is identified by the error encoder-decoder 508 for the particular die, then a scrub operation is not initiated because the scrub operation is unlikely to remedy future errors. By avoiding scrub operations that are less likely to be successful and are less likely to remedy future errors, time and power can be saved, and bandwidth utilization can be reserved for more productive operations.

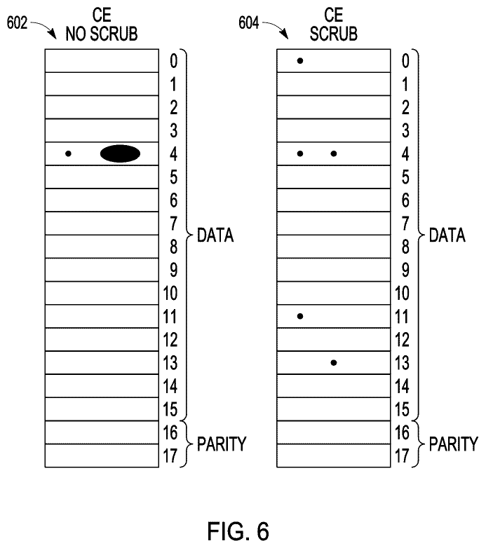

FIG. 6 illustrates generally pictorial representations of examples of different CE patterns observed by the error encoder-decoder 508 in data from the memory array 510. In a first instance of the array 602, multiple correctable errors are observed or detected in die 4. The pictorial representation indicates that, of the 32 total bits read from die 4, there is a portion with a single isolated bit error and another portion with a cluster of additional bit errors. The cluster can represent, for example, four or more bit errors. The cluster of bit errors can represent bit errors that correspond to physically adjacent or nearby memory cells in the array. If the correctable error threshold for triggering a scrub operation is two bit errors, then no scrub operation will be triggered for the data read from die 4 of the first instance of the array 602 because the number of errors exceeds the threshold. In this case, the error associated with die 4 is likely to be an uncorrectable error, and scrubbing is unlikely to help avoid future errors.

In a second instance of the array 604, multiple correctable errors are observed or detected in multiple dies. For example, single bit errors can be observed in dies 0, 11, and 13, and a pair of bit errors can be observed in die 4. In this example, if the correctable error threshold for triggering a scrub operation is two bit errors, then a scrub operation will be triggered for the data read from each of dies 0, 4, 11, and 13, because each die is responsible for two or fewer correctable errors (i.e., soft errors), which can be handled by the error encoder-decoder 508 and which may not be uncorrectable errors.

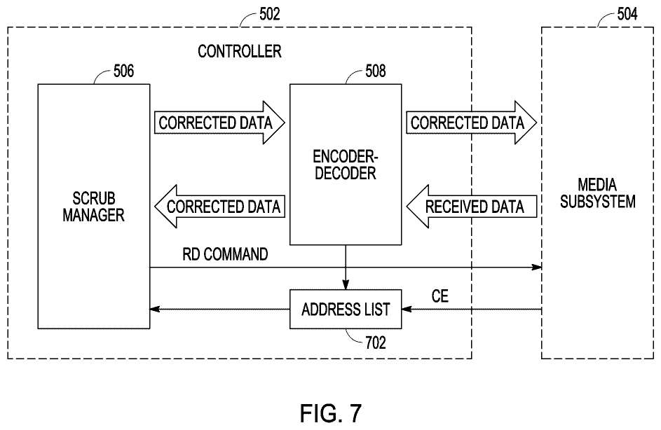

FIG. 7 illustrates generally an example that can include using the scrub manager 506 to postpone one or more scrub operations. For example, the memory controller 502 can include or use an address list 702 to store information about one or more memory locations (e.g., locations in the memory array 510 of the media subsystem 504) to scrub when resources are available, or at a particular scheduled time.

In an example, the address list 702 can be populated using information from the error encoder-decoder 508 about one or more correctable errors identified in data received from the memory array 510. In an example, the address list 702 can be populated with error address information contemporaneously with identification of an error by the error encoder-decoder 508.

Postponing scrub operations, however, can consume additional system resources because an additional read command can be used to retrieve the data to scrub from the memory array 510. That is, the scrub manager 506 can send a read command (RD) using the one or more addresses from the address list 702, and then scrub operations can be performed, including reading received data, correcting data using the error encoder-decoder 508, and writing the corrected data back into the memory array 510. Nevertheless, consuming additional system resources to perform postponed scrub operations at a scheduled time, or during other times of reduced system utilization, may be preferred over completing scrub operations contemporaneously with error identification.

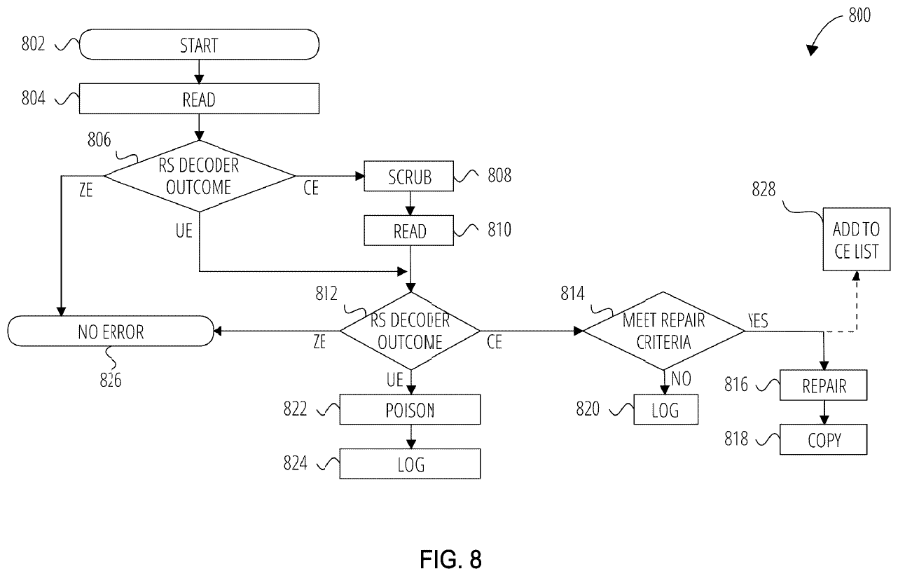

FIG. 8 illustrates generally a method 800 for a memory device maintenance flow that can include one or multiple scrub operations or scrub operation cycles. In an example, a memory device can enforce multiple different maintenance and scrub policies. For example, a periodic-based scrub policy, or patrol scrub, can be performed according to a specified cadence, such as daily. For example, after each 24 hour period of operation, each row in the memory array 510 can be read, corrected, and re-written.

In an example, an activity-based, CE-triggered scrub policy can include an on-demand policy. In an on-demand policy, for each detected CE, the corrected data (e.g., provided by the error encoder-decoder 508) can be written back to the memory array 510 in the same location from which the data was read. In an example, the on-demand policy can be enhanced or improved by including a re-read operation to capture hard fails. For example, reading a scrubbed data entry more than once can help in classifying an error as a soft error or a hard error, which in turn can lead to a more efficient and effective remedy. Furthermore, host notification about error events can be reserved for persistent errors, thereby reducing interlink (e.g., CXL interlink) traffic. The method 800 includes an example of an on-demand policy with data re-reading.

The method 800 can begin at operation 802 and perform a data read (RD) at operation 804. The data read from memory at operation 804 can be processed by a decoder (e.g., an RS decoder) at decision operation 806. The outcome of the decoder processing can be one of zero error (ZE), uncorrectable error (UE), or correctable error (CE). If an error is identified by the decoder, then the decoder can be configured to determine a quantity of correctable errors and uncorrectable errors in the data. In an example, the decoder can be configured to determine a relationship between the determined quantity of correctable errors and a specified threshold quantity of correctable errors and, based on the relationship, selectively perform (e.g., allow) or inhibit (e.g., disallow) a data scrub operation using the memory location from which the data was read at operation 804. In an example, the decoder can be configured to determine a distribution of the errors with various degrees of granularity. For example, the decoder can be configured to determine the error distribution among one or multiple memory devices, memory arrays, or rows, columns, or cells of an array. The decoder can be further configured to determine whether the error distribution includes a cluster of errors, such as can represent multiple errors in the same row or column, or in multiple adjacent or nearby rows or columns of a particular die.

At decision operation 806, if the outcome is ZE, then no error is present in the data and other operations of the memory device can proceed. If, at decision operation 806, the outcome is CE, then at operation 808 a scrub manager can perform a scrub operation, for example using the corrected data from the decoder and the memory location corresponding to the read at operation 804. In an example, the scrub manager can be configured to perform the scrub operation (e.g., at operation 808) only when a number of correctable errors for a particular die is less than a specified threshold number of correctable errors. At operation 810, the same memory location can be read again and, at decision operation 812, can be processed again by the decoder (e.g., the same or different decoder). Returning to decision operation 806, if the outcome is UE, then the method 800 can proceed to decision operation 812.

Outcomes from decision operation 812 can be ZE, UE, and CE. If the outcome of the decision operation 812 is ZE, then the CE identified at decision operation 806 was successfully corrected by the scrub operation 808, and no further error is detected. If the outcome of the decision operation 812 is UE, then the controller can notify the host, such as by sending a poison message to the host at operation 822, and the controller can log the event at operation 824. In response, the host can take other corrective actions, such as offlining one or more pages of the array, or employing other RAS mechanisms to deal with the detected UE. If the outcome of the decision operation 812 is CE, then the error can be considered a hard error. That is, because the error was encountered twice (once following decision operation 806, and once following decision operation 812), the error is unlikely to be correctable using an additional scrub operation, and therefore the error can be classified as a hard error.

At decision operation 814, the CE, or hard error, identified at decision operation 812 can be analyzed to determine whether repair criteria are met. If the repair criteria are not met, then the decision can be logged at operation 820, and the host can optionally determine other mitigation operations to perform. If, at decision operation 814, the repair criteria are met, then a repair can be performed at operation 816 and the data can be copied to a new location in the memory array at operation 818. In an example, operation 816 can include a post package repair to remap accesses from the faulty row associated with the CE to a different row. In an example, information about the CE identified at decision operation 812 can be stored or added to a CE list (e.g., corresponding to the address list 702) at operation 828, for example, after a repair operation is completed.

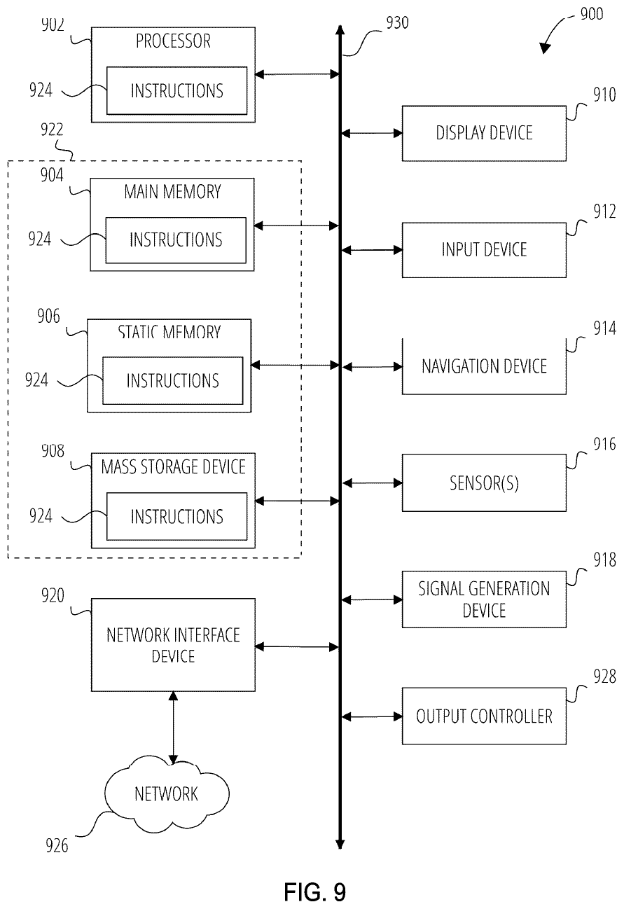

FIG. 9 illustrates a block diagram of an example machine 900 with which, in which, or by which any one or more of the techniques (e.g., methodologies) discussed herein can be implemented. Examples, as described herein, can include, or can operate by, logic or a number of components, or mechanisms in the machine 900. Circuitry (e.g., processing circuitry) is a collection of circuits implemented in tangible entities of the machine 900 that include hardware (e.g., simple circuits, gates, logic, etc.). Circuitry membership (e.g., as belonging to a host-side device or process, or to an accelerator-side device or process) can be flexible over time. Circuitries include members that can, alone or in combination, perform specified operations when operating. In an example, hardware of the circuitry can be immutably designed to carry out a specific operation (e.g., hardwired) for example using the device logic and memory controller 224, or a host interface circuit, or using a specific command execution unit thereof, such as to monitor or track correctable errors in a memory device and, based on a correctable error pattern, selectively allow or disallow scrub operations to help mitigate or avoid future uncorrectable errors in problematic die areas. In an example, the hardware of the circuitry can include variably connected physical components (e.g., command execution units, transistors, simple circuits, etc.) including a machine-readable (e.g., processor-readable) medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components can be used in more than one member of more than one circuitry. For example, under operation, execution units can be used in a first circuit of a first circuitry at one point in time and reused by a second circuit in the first circuitry, or by a third circuit in a second circuitry at a different time.

In alternative embodiments, the machine 900 can operate as a standalone device or can be connected (e.g., networked) to other machines. In a networked deployment, the machine 900 can operate in the capacity of a server machine, a client machine, or both in server-client network environments. In an example, the machine 900 can act as a peer machine in peer-to-peer (P2P) (or other distributed) network environment. The machine 900 can be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Any one or more of the components of the machine 900 can include or use one or more instances of the host device 202 or the CXL device 204 or other component in or appurtenant to the computing system 100. The machine 900 (e.g., computer system) can include a hardware processor 902 (e.g., the host processor 216, the device logic and memory controller 224, a central processing unit (CPU), a graphics processing unit (GPU), a hardware processor core, or any combination thereof), a main memory 904, a static memory 906 (e.g., memory or storage for firmware, microcode, a basic-input-output (BIOS), unified extensible firmware interface (UEFI), etc.), and mass storage device 908 or memory die stack, hard drives, tape drives, flash storage, or other block devices) some or all of which can communicate with each other via an interlink 930 (e.g., bus). The machine 900 can further include a display device 910, an alphanumeric input device 912 (e.g., a keyboard), and a user interface (UI) Navigation device 914 (e.g., a mouse). In an example, the display device 910, the input device 912, and the UI navigation device 914 can be a touch screen display. The machine 900 can additionally include a mass storage device 908 (e.g., a drive unit), a signal generation device 918 (e.g., a speaker), a network interface device 920, and one or more sensor(s) 916, such as a global positioning system (GPS) sensor, compass, accelerometer, or other sensor. The machine 900 can include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the hardware processor 902, the main memory 904, the static memory 906, or the mass storage device 908 can be, or include, a machine-readable media 922 on which is stored one or more sets of data structures or instructions 924 (e.g., software) embodying or used by any one or more of the techniques or functions described herein. The instructions 924 can also reside, completely or at least partially, within any of registers of the hardware processor 902, the main memory 904, the static memory 906, or the mass storage device 908 during execution thereof by the machine 900. In an example, one or any combination of the hardware processor 902, the main memory 904, the static memory 906, or the mass storage device 908 can constitute the machine-readable media 922. While the machine-readable media 922 is illustrated as a single medium, the term “machine-readable medium” can include a single medium or multiple media (e.g., a centralized or distributed database, or associated caches and servers) configured to store the one or more instructions 924.

The term “machine-readable medium” (or, equivalently, “processor-readable medium”) can include any medium that is capable of storing, encoding, or carrying instructions for execution by the machine 900 and that cause the machine 900 to perform any one or more of the techniques of the present disclosure, or that is capable of storing, encoding or carrying data structures used by or associated with such instructions. Non-limiting machine-readable medium examples can include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine readable media that do not include transitory propagating signals. Specific examples of non-transitory machine readable media can include: non-volatile memory, such as semiconductor memory devices (e.g., electrically programmable read-only memory (EPROM), electrically erasable programmable read-only memory (EEPROM)) and flash memory devices; magnetic disks, such as internal hard disks and removable disks; magneto-optical disks; and CD-ROM and DVD-ROM disks.

In an example, information stored or otherwise provided on the machine-readable media 922 can be representative of the instructions 924, such as instructions 924 themselves or a format from which the instructions 924 can be derived. This format from which the instructions 924 can be derived can include source code, encoded instructions (e.g., in compressed or encrypted form), packaged instructions (e.g., split into multiple packages), or the like. The information representative of the instructions 924 in the machine-readable media 922 can be processed by processing circuitry into the instructions to implement any of the operations discussed herein. For example, deriving the instructions 924 from the information (e.g., processing by the processing circuitry) can include: compiling (e.g., from source code, object code, etc.), interpreting, loading, organizing (e.g., dynamically or statically linking), encoding, decoding, encrypting, unencrypting, packaging, unpackaging, or otherwise manipulating the information into the instructions 924.

In an example, the derivation of the instructions 924 can include assembly, compilation, or interpretation of the information (e.g., by the processing circuitry) to create the instructions 924 from some intermediate or preprocessed format provided by the machine-readable media 922. The information, when provided in multiple parts, can be combined, unpacked, and modified to create the instructions 924. For example, the information can be in multiple compressed source code packages (or object code, or binary executable code, etc.) on one or several remote servers. The source code packages can be encrypted when in transit over a network and decrypted, uncompressed, assembled (e.g., linked) if necessary, and compiled or interpreted (e.g., into a library, stand-alone executable etc.) at a local machine, and executed by the local machine.

The instructions 924 can be further transmitted or received over a communications network 926 using a transmission medium via the network interface device 920 utilizing any one of a number of transfer protocols (e.g., frame relay, internet protocol (IP), transmission control protocol (TCP), user datagram protocol (UDP), hypertext transfer protocol (HTTP), etc.). Example communication networks can include a local area network (LAN), a wide area network (WAN), a packet data network (e.g., the Internet), mobile telephone networks (e.g., cellular networks), plain old telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 920 can include one or more physical jacks (e.g., Ethernet, coaxial, or phone jacks) or one or more antennas to connect to the network 926. In an example, the network interface device 920 can include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 900, and includes digital or analog communications signals or other intangible medium to facilitate communication of such software. A transmission medium is a machine-readable medium.

To illustrate the methods and apparatuses discussed herein, a non-limiting set of Example embodiments are set forth below as numerically-identified Examples.

Example 1 is a method comprising receiving first data from a first portion of a memory device array, determining a quantity of correctable errors in the first data (e.g., performing a count of a number of correctable errors detected), and determining a relationship between the determined quantity of correctable errors and a specified threshold quantity of correctable errors. In Example 1, based on the relationship, the method includes one of (a) performing a data scrub operation using the first data and the first portion of the memory array or (b) inhibiting a data scrub operation using the first data and the first portion of the memory array. Determining the quantity of correctable errors can be performed using an RAS scheme, such as including using a Reed-Solomon ECC.

In Example 2, the subject matter of Example 1 includes determining the quantity of correctable errors in the first data using a Reed-Solomon error-correcting code.

In Example 3, the subject matter of Examples 1-2 includes or uses the first portion of the memory device comprising a first die of multiple dies in the memory device array, and determining the quantity of correctable errors in the first data includes determining the quantity of correctable errors in the first die.

In Example 4, the subject matter of Examples 1-3 includes performing or inhibiting the data scrub operation including performing the data scrub operation when the determined quantity of correctable errors is less than the specified threshold quantity of correctable errors, and inhibiting the data scrub operation when the determined quantity of correctable errors meets or exceeds the specified threshold quantity of correctable errors.

In Example 5, the subject matter of Examples 1-4 includes determining the first data includes a cluster of bit errors in the first data, wherein the cluster of bit errors corresponds to information from two or more adjacent cells, rows, or columns in a particular die of the memory device array.

In Example 6, the subject matter of Example 5 includes performing or inhibiting the data scrub operation including inhibiting the data scrub operation when the first data includes the cluster of bit errors.

In Example 7, the subject matter of Examples 1-6 includes the first portion of the memory device array comprising multiple dies in the memory device array, and determining the quantity of correctable errors in the first data includes determining respective quantities of correctable errors in each of the multiple dies.

In Example 8, the subject matter of Example 7 includes determining a distribution of correctable errors among the multiple dies, and performing or inhibiting the data scrub operation using the first data based on the determined distribution.

In Example 9, the subject matter of Examples 1-8 includes performing the data scrub operation using the first data from the first portion of the memory array, receiving second data from the same first portion of the memory device array, determining a second quantity of correctable errors in the second data, and responsive to the second quantity of correctable errors in the second data meeting the specified threshold quantity of correctable errors, inhibiting a second data scrub operation.

In Example 10, the subject matter of Example 9 includes notifying a host device that the first portion of the memory array contains an uncorrectable error.

In Example 11, the subject matter of Examples 1-10 includes performing the data scrub operation using the first data from the first portion of the memory array, receiving second data from the same first portion of the memory device array, determining a second quantity of correctable errors in the second data, and responsive to the second quantity of correctable errors in the second data being less than the specified threshold quantity of correctable errors, determining whether a repair criteria is met for the first portion of the memory array. Example 11 can further include performing a post package repair operation for the first portion of the memory array.

Example 12 is a system comprising a host device and a memory device coupled to the host device, wherein the memory device comprises a memory device controller configured to monitor correctable error accumulation in each of multiple regions of a memory array and conditionally trigger a scrub operation based on a number of correctable errors observed.

In Example 13, the subject matter of Example 12 includes or uses the memory device controller configured to perform the scrub operation for particular data read from a first region of the memory array when the error accumulation associated with the first region of the memory array indicates less than a threshold number of correctable errors.

In Example 14, the subject matter of Example 13 includes or uses the memory device controller configured to not perform the scrub operation for the particular data when the error accumulation associated with the first region of the memory array indicates at least the threshold number of correctable errors.

In Example 15, the subject matter of Examples 13-14 includes the first region of the memory array comprises a first die of multiple dies in the memory array.

In Example 16, the subject matter of Examples 13-15 includes the first region of the memory array comprises a first row or a first column of memory cells in the memory array.

In Example 17, the subject matter of Examples 13-16 includes the memory device controller is configured to monitor the correctable error accumulation for the same regions of the memory array over multiple scrub operation cycles and, in response to identify the same correctable errors in the same regions of the memory array over multiple scrub operation cycles, the memory device controller is configured to notify the host device that the memory array includes one or more regions for repair or remapping.

In Example 18, the subject matter of Examples 13-17 includes the memory device is coupled to the host device using a compute express link (CXL) interconnect.

Example 19 is a non-transitory processor-readable storage medium, the processor-readable storage medium including instructions that, when executed by a processor circuit, cause the processor circuit to: read first data from a first portion of an array of a memory device; use an error-correcting code decoder to determine a number of correctable errors present in the first data; in response to the number of correctable errors being less than a specified threshold number of correctable errors, perform a scrub operation using the first data, the scrub operation including determining corrected data based on the first data and writing the corrected data to the first portion of the array of the memory device; and in response to the number of correctable errors being greater than or equal to a specified threshold number of correctable errors, disallow the scrub operation.

In Example 20, the subject matter of Example 19 includes the processor-readable storage medium including further instructions that, when executed by the processor circuit, cause the processor circuit to: read second data from the first portion of the array of the memory device; determine whether the second data includes the same number of correctable errors present in the first data; and in response to determining the second data includes the same number of correctable errors, perform a repair operation on the first portion of the array of the memory device.

Example 21 is an apparatus comprising means to implement of any of Examples 1-20.

Example 22 is a system to implement of any of Examples 1-20.

Each of these non-limiting Examples can stand on its own, or can be combined in various permutations or combinations with one or more of the other examples discussed herein.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” can include “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) can be used in combination with each other. Other embodiments can be used, such as by one of ordinary skill in the art upon reviewing the above description. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A method comprising:
receiving first data from a first portion of a memory device array;
determining a quantity of correctable errors in the first data; and
determining a relationship between the determined quantity of correctable errors and a specified threshold quantity of correctable errors and, based on the relationship, one of performing a data scrub operation using the first data and the first portion of the memory array or inhibiting a data scrub operation using the first data and the first portion of the memory array.

2. The method of claim 1, wherein determining the quantity of correctable errors in the first data includes using a Reed-Solomon error-correcting code.

3. The method of claim 1, wherein the first portion of the memory device array comprises a first die of multiple dies in the memory device array, and wherein determining the quantity of correctable errors in the first data includes determining the quantity of correctable errors in the first die.

4. The method of claim 1, wherein performing or inhibiting the data scrub operation includes performing the data scrub operation when the determined quantity of correctable errors is less than the specified threshold quantity of correctable errors, and inhibiting the data scrub operation when the determined quantity of correctable errors meets or exceeds the specified threshold quantity of correctable errors.

5. The method of claim 1, further comprising determining the first data includes a cluster of bit errors in the first data, wherein the cluster of bit errors corresponds to information from two or more adjacent cells, rows, or columns in a particular die of the memory device array.

6. The method of claim 5, wherein performing or inhibiting the data scrub operation includes inhibiting the data scrub operation when the first data includes the cluster of bit errors.

7. The method of claim 1, wherein the first portion of the memory device array comprises multiple dies in the memory device array, and wherein determining the quantity of correctable errors in the first data includes determining respective quantities of correctable errors in each of the multiple dies.

8. The method of claim 7, further comprising determining a distribution of correctable errors among the multiple dies, and performing or inhibiting the data scrub operation using the first data based on the determined distribution.

9. The method of claim 1, further comprising:
performing the data scrub operation using the first data from the first portion of the memory array;
receiving second data from the same first portion of the memory device array;
determining a second quantity of correctable errors in the second data; and
responsive to the second quantity of correctable errors in the second data meeting the specified threshold quantity of correctable errors, inhibiting a second data scrub operation.

10. The method of claim 9, further comprising notifying a host device that the first portion of the memory array contains an uncorrectable error.

11. The method of claim 1, further comprising:
performing the data scrub operation using the first data from the first portion of the memory array;
receiving second data from the same first portion of the memory device array;
determining a second quantity of correctable errors in the second data; and
responsive to the second quantity of correctable errors in the second data being less than the specified threshold quantity of correctable errors, determining whether a repair criteria is met for the first portion of the memory array and selectively performing a post package repair operation for the first portion of the memory array.

12. A system comprising:
a host device; and
a memory device coupled to the host device, wherein the memory device comprises a memory device controller configured to:
monitor correctable error accumulation in each of multiple regions of a memory array; and
conditionally trigger a scrub operation based on a number of correctable errors observed.

13. The system of claim 12, wherein the memory device controller is configured to perform the scrub operation for particular data read from a first region of the memory array when the error accumulation associated with the first region of the memory array indicates less than a threshold number of correctable errors.

14. The system of claim 13, wherein the memory device controller is configured to not perform the scrub operation for the particular data when the error accumulation associated with the first region of the memory array indicates at least the threshold number of correctable errors.

15. The system of claim 13, wherein the first region of the memory array comprises a first die of multiple dies in the memory array.

16. The system of claim 13, wherein the first region of the memory array comprises a first row or a first column of memory cells in the memory array.

17. The system of claim 13, wherein the memory device controller is configured to monitor the correctable error accumulation for the same regions of the memory array over multiple scrub operation cycles and, in response to identify the same correctable errors in the same regions of the memory array over multiple scrub operation cycles, the memory device controller is configured to notify the host device that the memory array includes one or more regions for repair or remapping.

18. The system of claim 13, wherein the memory device is coupled to the host device using a compute express link (CXL) interconnect.

19. A non-transitory processor-readable storage medium, the processor-readable storage medium including instructions that, when executed by a processor circuit, cause the processor circuit to:
read first data from a first portion of an array of a memory device;
use an error-correcting code decoder to determine a number of correctable errors present in the first data;
in response to the number of correctable errors being less than a specified threshold number of correctable errors, perform a scrub operation using the first data, the scrub operation including determining corrected data based on the first data and writing the corrected data to the first portion of the array of the memory device; and
in response to the number of correctable errors being greater than or equal to a specified threshold number of correctable errors, disallow the scrub operation.

20. The non-transitory processor-readable storage medium of claim 19, wherein the processor-readable storage medium includes further instructions that, when executed by the processor circuit, cause the processor circuit to:
read second data from the first portion of the array of the memory device;
determine whether the second data includes the same number of correctable errors present in the first data; and
in response to determining the second data includes the same number of correctable errors, perform a repair operation on the first portion of the array of the memory device.
